(19) United States
(12) Patent Application Publication
(10) Pub. No.: US 2011/0239933 A1
(43) Pub. Date: Oct. 6, 2011

(54) DEVICE AND METHOD FOR THE PRODUCTION OF SILICON BLOCKS

(76) Inventors: Bernhard FREUDENBERG, Coburg (DE); Günter RADEL, Nurnberg (DE); Matthias TREMPA, Erlangen (DE); Kaspars DADZIS, Freiberg (DE); Marc DIETRICH, Grossschirma (DE); Doreen NAUERT, Grossschirma (DE); Stefan PROSKE, Klipphausen (DE); Christian REIMANN, Munchaurach (DE); Jochen FRIEDRICH, Eckental (DE)

(21) Appl. No.: 13/075,293

(22) Filed: Mar. 30, 2011

(30) Foreign Application Priority Data
Apr. 1, 2010 (DE) 10 2010 013 904.1
Apr. 1, 2010 (DE) 10 2010 013 906.8
Apr. 12, 2010 (DE) 10 2010 014 723.0
Apr. 12, 2010 (DE) 10 2010 014 724.9

(51) Int. Cl. C30B 11/00; B29C 33/38

(52) U.S. Cl. 117/223; 264/219

(57) ABSTRACT

Device for the production of silicon blocks, the device comprising a vessel for receiving a silicon melt with a bottom, an inside, an outside and a central longitudinal axis and at least one support plate which is at least partially in direct contact with the bottom, and which forms a base together with the bottom, and means for generating an inhomogeneous temperature field on the inside of the bottom.

### BACKGROUND OF THE INVENTION

1. Field of the Invention

The invention relates to a device and a method for the production of silicon blocks. The invention furthermore relates to a method for the production of such a device.

2. Background Art

The production of large-volume silicon blocks is a key step in the production process of silicon solar cells. This method step has a decisive influence on the future properties of the semiconductor material, in particular on the achievable efficiency of the finished solar cells.

Devices and methods for the production of silicon blocks are for example disclosed in WO 2007/148987 A1 and in DE 24 61 553 C2.

There is however always the need to improve the controllability and reproducibility as well as the cost-effectiveness of such methods.

### SUMMARY OF THE INVENTION

It is therefore the object of the invention to improve a device and a method for the production of silicon blocks.

This object is achieved by the features of a device for the production of silicon blocks, the device comprising a vessel for receiving a silicon melt, the vessel comprising a bottom, an inside, an outside and a central longitudinal axis, with the bottom having an extension in a direction perpendicular to the central longitudinal axis and, along its extension in the direction perpendicular to the central longitudinal axis, comprising at least two regions with different heat transfer coefficients.

Furthermore, this object is achieved by a method for the production of a device according to the invention, wherein in order to produce the vessel, a green body is produced in a first step.

Finally, this object is achieved by the features of a device for the production of silicon blocks, the device comprising a vessel for receiving a silicon melt, the vessel comprising a bottom, an inside, an outside and a central longitudinal axis, and at least one support plate which is at least partially in direct contact with the bottom and which forms a base together with the bottom, and means for generating an inhomogeneous temperature field on the inside of the bottom.

The gist of the invention is to design the bottom of a coquille in such a way that the melt in the coquille is in contact with a location-variable temperature field at the bottom thereof when subjected to directed cooling from below. According to the invention, this is in particular achieved by the bottom of the coquille having an inhomogeneous heat transfer coefficient. The bottom in particular comprises at least two regions having different heat transfer coefficients. This causes the melt in the region having a higher heat transfer coefficient to cool more rapidly, with the result that crystallization of the melt preferably starts in these regions. An advantage according to the invention is that this effect is relatively robust with respect to a variability of the melting furnace, in particular the temperature distribution therein.

Regions having different heat transfer coefficients are particularly simply achieved by the bottom having an inhomogeneous, in other words location-variable thickness. The thermal conductivity of the bottom may be constant, in other words the bottom may be made homogeneously of a single material.

A targeted arrangement of recesses, in other words regions of reduced thickness, allows a bottom to be produced so as to have a predetermined heat transfer coefficient distribution in a very specific and targeted manner. In order to minimize variability of the heat transfer coefficient in the remaining regions, the bottom preferably has a homogeneous thickness except for the recesses Instead of the recesses, it is also conceivable to provide corresponding reinforcements.

It is advantageous both in terms of production and removal of the silicon block from the coquille to arrange the recesses on the outside of the bottom.

Depending on the material of the coquille and the thermal properties of the insulation surrounding the coquille, the recesses have a size in the order of magnitude of millimeters to centimeters.

In order to cool the silicon melt in the coquille, heat is—according to the inventive method—dissipated through the bottom of the coquille in such a way that an inhomogeneous temperature distribution is achieved at least temporarily in the region of the bottom on the inside of the coquille. This allows the crystallization process, in particular the nucleation at the bottom of the coquille, to be influenced in a targeted manner.

Temperature differences of 0.1 to 50 Kelvin in the region of the coquille bottom may have a decisive influence on nucleation and therefore on volume crystallization.

It is intended for the coquille to be made of a ceramic material. To this end, an appropriate green body is formed in a first step. According to a first variant, it is intended to structure the green body prior to curing. The advantage of this variant is that in this state, the green body is still relatively soft and therefore easy to process.

According to an embodiment, it is intended to structure the green body in an after treatment step performed after hardening. This allows the coquille to be structured in a very precise manner.

Another aspect of the invention is to design the base of a coquille in such a way that when the melt is subjected to directed cooling from below, it is in contact with a location-variable temperature field at the bottom of the coquille. According to the invention, this is achieved in particular by providing the support plate underneath the bottom of the coquille with an inhomogeneous heat transfer coefficient. The support plate comprises in particular at least two regions having different heat transfer coefficients. This causes the melt in the region having a higher heat transfer coefficient to cool more rapidly, with the result that crystallization of the melt preferably starts in these regions. At least one of the support plate and the bottom of the coquille may comprise a plurality of such regions which act as heat sinks. As such, they will define the distribution of nucleation sites on the inside of the bottom of the coquille. An advantage according to the invention is that this effect is relatively robust with respect to a variability of the melting furnace, in particular the temperature distribution therein.

Regions having different heat transfer coefficients in the base are achieved in a particularly simple manner by providing the support plate with an inhomogeneous, in other words location-variable thickness. As an alternative or in addition thereto, the bottom of the coquille may have an inhomogeneous thickness as well. The thickness of the bottom may however also be homogeneous, in other words constant. The thermal conductivity of the support plate and of the bottom may be constant, in other words they may in each case be made of a single material. The support plate may alternatively be made of a combination of several materials having different thermal conductivities.

A cooling device allows heat dissipation in the region of the base, in particular in the region of the coquille bottom, to be influence in a particularly efficient and targeted manner.

The effect of the cooling device on heat dissipation depends, among other things, on its spatial arrangement relative to the coquille bottom, in particular on the temperature gradient between coquille bottom and cooling duct, as well as on the geometric dimensions of the cooling duct, in particular the volume flow through said cooling duct.

A targeted arrangement of recesses, in other words regions of reduced thickness, allows a support plate and a bottom as well as a base having a predetermined heat transfer coefficient to be produced in a very specific manner. In order to minimize variability of the heat transfer coefficient in the remaining regions, the support plate advantageously has a homogeneous thickness except for the recesses. Instead of the recesses, it is conceivable as well to provide corresponding reinforcements.

In order to cool the silicon melt in the coquille, heat is—according to the inventive method—dissipated through the bottom of the coquille in such a way that an inhomogeneous temperature distribution is achieved at least temporarily in the region of the bottom on the inside of the coquille. This allows a targeted influence to be exerted on the crystallization process, in particular the nucleation at the bottom of the coquille.

Temperature differences of 0.1 to 50 Kelvin in the region of the coquille bottom may have a decisive influence on nucleation and therefore on volume crystallization.

According to another aspect of the invention the recesses have a depth in the range of no more than 1 cm, in particular of no more than 5 mm, in the direction of the central longitudinal axis.

According to another aspect of the invention the recesses have an expansion in the range of no more than 5 cm, in particular of no more than 1 cm, in the direction perpendicular to the central longitudinal axis.

According to another aspect of the invention said the temperature distribution in the region of the bottom of the inside of the vessel comprises a temperature range of at least 1 K, in particular of at least 5 K and no more than 10 K.

Features and details of the invention will become apparent from the description of several embodiments by means of the drawing.

### BRIEF DESCRIPTION OF THE DRAWING

FIG. 1 is a schematic cross-section through a first embodiment of a device according to the invention; and

FIGS. 2 to 16 are corresponding illustrations of further embodiments according to the invention.

### DESCRIPTION OF THE PREFERRED EMBODIMENT

The following is a description of a first embodiment of the invention with reference to FIG. 1. A device 1 according to the invention for the production of silicon blocks comprises a vessel 2 for receiving a silicon melt and a support plate 3 for the vessel 2.

The vessel 2 is in particular a pot or a coquille. The vessel 2 has a bottom 4 and at least one side wall 5. The bottom 4 and the at least one side wall 5 in each case have an inside 6 and an outside 7.

The vessel 2 is symmetric relative to a central longitudinal axis 8. The central longitudinal axis 8 is in particular perpendicular to the bottom 4. The vessel 2 preferably has a rectangular, square or circular cross-section.

The vessel 2 is preferably made of ceramics and contains in particular at least a proportion of silicon dioxide, silicon nitride, silicon oxynitride or silicon carbide. The vessel 2 may also contain proportions of graphite or consist of graphite.

In the direction which is perpendicular to the central longitudinal axis 8, the bottom 4 has an extension in the range of 10 cm to 200 cm, in particular of at least 25 cm, preferably of at least 50 cm. In the region of the bottom 4, the wall thickness is in the range of 1 cm to 5 cm, in particular in the range of 2 cm to 3 cm. In the direction of the central longitudinal axis 8, the side walls 5 have an extension in the range of 20 cm to 150 cm, in particular in the range of 50 cm to 110 cm. The side walls 5 form an angle b with the bottom 4 of at least 90°. The angle b is preferably in the range of 92° to 100°, in particular in the range of 95° to 98°. In other words, the vessel 2 becomes wider when seen from the bottom in the direction of the central longitudinal axis 8. This simplifies a removal of the silicon block after crystallization thereof.

At least some regions of the support plate 3 are in direct contact with the bottom 4. The support plate 3 forms a base 9 together with the bottom 4. The support plate 3 may be of one or multiple pieces. It comprises in particular one or multiple layers. The support plate 3 has a thickness DT. It has dimensions in the direction which is perpendicular to the central longitudinal axis 8 which are at least equal to but in particular at least 1.1 times the size of the dimensions of the bottom 4 of the vessel 2. The support plate 3 advantageously protrudes beyond the bottom 4 of the vessel 2 in the direction perpendicular to the central longitudinal axis 8.

The support plate 3 consists of a material with a high thermal conductivity. The thermal conductivity of the material of the support plate 3 amounts to at least 10 W/(mK). The support plate 3 consists in particular at least partially of graphite. It may also consist entirely of graphite.

According to the invention, means for generating an inhomogeneous temperature field are provided on the inside 6 of the bottom 4. To this end, the base 9 is designed in such a way as to have an inhomogeneous heat transfer coefficient U. In other words, the base 9 comprises at least two regions having different heat transfer coefficients U₁, U₂ relative to the direction of the central longitudinal axis 8.

According to the embodiment shown in FIG. 1, this is achieved by the bottom 4 comprising at least two regions having different heat transfer coefficients U_{B1}, U_{B2}. This is achieved by the bottom 4 having an inhomogeneous thickness D. The term “inhomogeneous thickness” means that the thickness D of the bottom 4 is not constant in the direction perpendicular to the central longitudinal axis 8, i.e. the thickness D varies. In other words, the bottom 4 comprises at least one region of a lower thickness than the rest of the bottom 4.

The thermal conductivity of the bottom 4 on the other hand may be constant across the entire extension of the bottom 4. The bottom 4 may in particular be made of a single material and thus have a constant thermal conductivity. Regions of the bottom 4 may also be made of different materials.

The thickness distribution of the bottom 4 is achieved by the bottom 4 comprising a multitude of recesses 10. The bottom 4 in particular comprises at least one recess 10. According to the embodiment shown in FIG. 1, the recesses 10 are arranged on the outside 7 of the bottom 4. The inside 6 of the bottom 4 may be plane. Apart from the recesses 10, the bottom 4 has a homogeneous thickness D₀.

The recesses 10 are designed in the manner of a blind hole. According to the embodiment shown in FIG. 1, they have a cylindrical shape. The recesses 10 may have a round, in particular a circular, or a polygonal, in particular a triangular, rectangular, hexagonal or polygonal cross-section. In the direction of the central longitudinal axis 8, they have a depth in the range of 0.5 mm to 2 cm, in particular of no more than 1 cm, in particular of no more than 5 mm. In the direction perpendicular to the central longitudinal axis 8, the extension of the recesses 10 is in the range of 1 mm to 20 cm, in particular no more than 5 cm, in particular no more than 1 cm.

The recesses 10 are arranged preferably regularly, in particular in a regular pattern, on the bottom 4 of the vessel 2. They are in particular arranged symmetrically relative to the central longitudinal axis 8. The pattern for arranging the recesses 10 may in particular be a triangular, a square or a hexagonal pattern. A circular arrangement of the recesses 10 is conceivable as well. According to the illustrated embodiment, all recesses 10 have identical dimensions. In an alternative embodiment, it may however be intended for different recesses 10 to have different dimensions, in particular different depths T or different extensions in the direction perpendicular to the central longitudinal axis 8.

The recesses 10 are arranged at a mutual distance A relative to each other. The distance A is in the range of 3 cm to 30 cm, in particular in the range of 5 cm to 20 cm. The number, the dimensions and the distribution of recesses 10 on the bottom 4 are adapted to each other in such a way that the recesses 10 have no detectable influence on the temperature field on the inside 6 of the bottom 4 in the region of adjacent recesses 10. The influence of a recess 10 on the temperature field on the inside 6 of the bottom 4 is in the range of 0.1 K to 50 K.

The number of recesses 10 in the bottom 4 is in the range of 1 to 500, in particular in the range of 4 to 100, preferably in the range of up to 50.

The following is a description of the method according to the invention for the production of silicon blocks. In a first step, the vessel 2 for receiving a silicon melt is provided and filled with a silicon melt. To this end, silicon may also be molten in the vessel 2. In order for the silicon melt to crystallize, the silicon melt is slowly cooled down starting from the bottom 4 of the vessel 2. Slow cooling means that the cooling process takes place at no more than 0.3° C./s, in particular no more than 0.1° C./s. In this process, heat is dissipated through the bottom 4 of the vessel 2. According to the invention, it is intended for heat dissipation to occur in such a way that an inhomogeneous temperature distribution is achieved in the region of the bottom 4 on the inside 6 of the vessel 2 at least temporarily, in particular when crystallization of the silicon melt starts. The regions having different heat transfer coefficients U_{B1}, U_{B2} in particular cause regions of higher and regions of lower temperature to form in the region of the bottom 4 on the inside 6 of the vessel 2.

When the silicon melt cools down in the region of the recesses 10, there is a higher heat emission in these regions compared to regions of the bottom 4 without recesses 10, which therefore results in a higher heat dissipation.

The temperature distribution on the inside 6 of the bottom 4 is in a temperature range of at least 0.1 K to 50 K, in particular at least 1 K, in particular at least 5 K and no more than 20 K, in particular no more than 10 K.

The regions of lower temperature form nucleation centers where crystallization of the silicon melt preferably starts. After the formation of crystallization nuclei in the regions of lower temperature, the temperature of the silicon melt is further reduced on the inside 6 of the bottom 4 at such a low cooling rate that the crystals forming from the nucleation centers in the regions of lower temperature will have completely grown over the regions of higher temperature before the temperature becomes so low that heterogeneous nucleation will occur in the latter regions.

In order to produce the vessel 2, a green body of the vessel 2 is produced in a first step. According to a first alternative, the bottom 4 of the vessel 2 is structured before the green body has cured. According to another alternative, the bottom 4 of the vessel 2 is not structured until the green body has cured. This alternative requires after-treatment, in particular drilling, milling or grinding.

The following is a description, with reference to FIG. 2, of another embodiment of the invention. Identical parts are denoted by the same reference numerals as in the first embodiment to the description of which reference is made. Differently designed parts having the same function are denoted by the same reference numerals with an a added to them. In the embodiment according to FIG. 2, the recesses 10a have a conical shape. Their extension in the direction perpendicular to the central longitudinal axis 8 increases towards the outside 7 of the bottom 4a. They are in particular arranged in such a way that two adjacent recesses 10a just abut each other on the outside 7 of the bottom 4. They may however also be spaced from each other. The recesses 10a are preferably arranged in a triangular, square or hexagonal pattern.

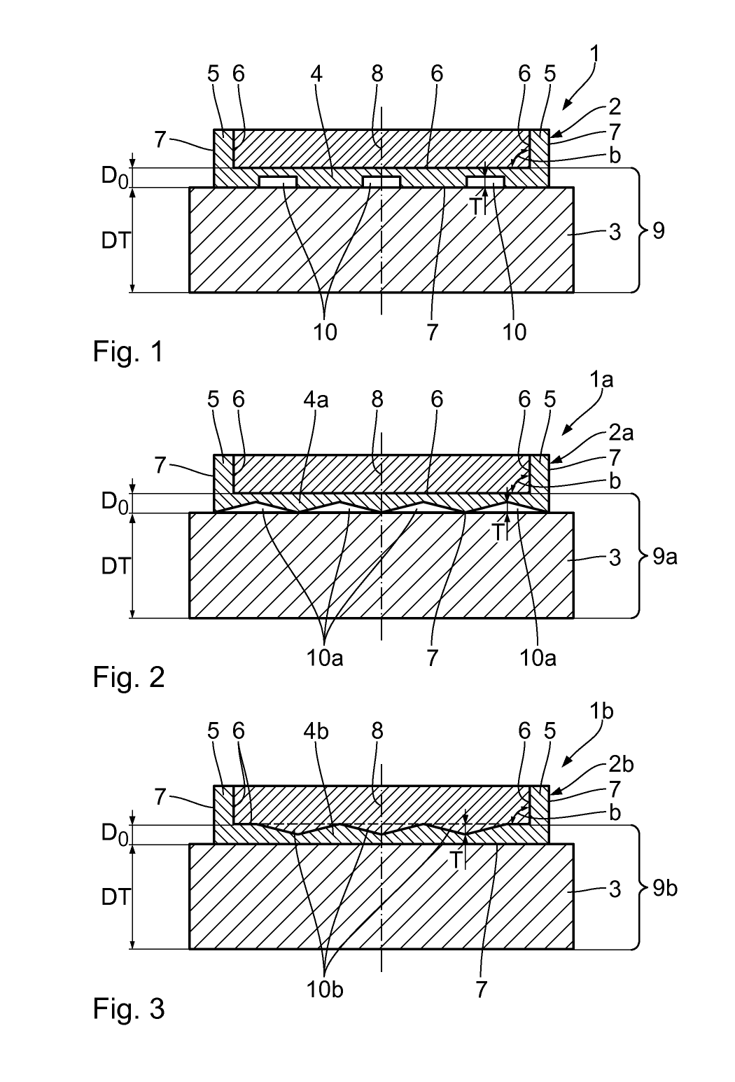

The following is a description, with reference to FIG. 3, of a third embodiment of the invention. Identical parts are denoted by the same reference numerals as in the first embodiment to the description of which reference is made. Differently designed parts having the same function are denoted by the same reference numerals with a b added to them. In the embodiment according to FIG. 3, the recesses 10b are arranged on the inside 6 of the bottom 4b. The outside 7 of the bottom 4 is in particular plane. In principle, it is conceivable as well to combine the recesses 10b on the inside 6 of the bottom 4b with recesses 10, 10a on the outside 7 of the bottom 4b.

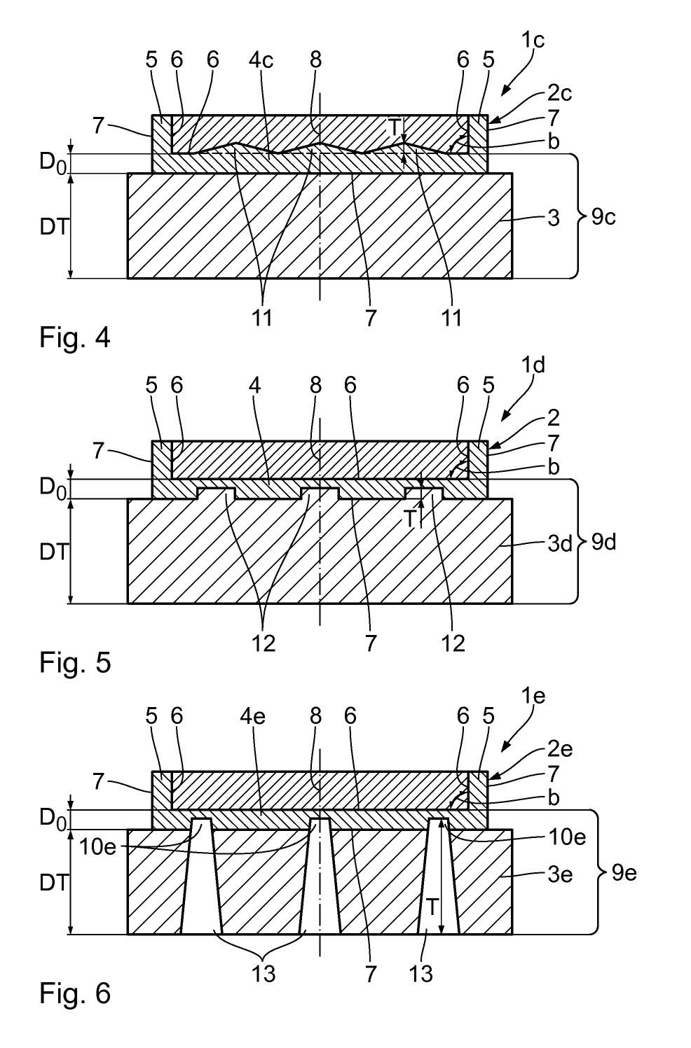

The following is a description, with reference to FIG. 4, of a fourth embodiment of the invention. Identical parts are denoted by the same reference numerals as in the first embodiment to the description of which reference is made. Differently designed parts having the same function are denoted by the same reference numerals with a c added to them. In the embodiment according to FIG. 4, reinforcements 11 are provided for influencing the heat transfer coefficient U of the bottom 4c. The bottom 4c thus has a locally increased thickness compared to the thickness D₀. The reinforcements are arranged on the inside 6 of the vessel 2c. Depending on their extension in the direction of the central longitudinal axis 8, the reinforcements 11 cause the heat transfer coefficient U of the bottom 4c to be reduced.

The reinforcements are preferably conical. Cylindrical reinforcements 11 are however conceivable as well.

In principle it is conceivable as well to design the reinforcements 11 in the manner of a template which may also be inserted in a coquille or a pot at a later time.

The following is a description, with reference to FIG. 5, of a fifth embodiment of the invention. Identical parts are denoted by the same reference numerals as in the first embodiment to the description of which reference is made. Differently designed parts having the same function are denoted by the same reference numerals with a d added to them. In the embodiment according to FIG. 5, the support plate 3d comprises projections 12 the shape of which is adapted to the recesses 10. The projections 12 are in particular adapted to be positively inserted into the recesses 10 in the bottom 4 of the vessel 2. The side of the support plate 3d facing the bottom 4 of the vessel 2 thus forms an inverted image of the bottom 4.

In this and the following embodiments, the inside 6 of the bottom 4 can be plane. It can also be structured according to the previously described embodiments.

In this embodiment, the entire bottom 4 of the vessel 2 is in direct contact with the support plate 3d. The direct contact between the bottom 4 and the support plate 3d even in the region of the recesses 10 increases the heat flow in the region of the recesses 10.

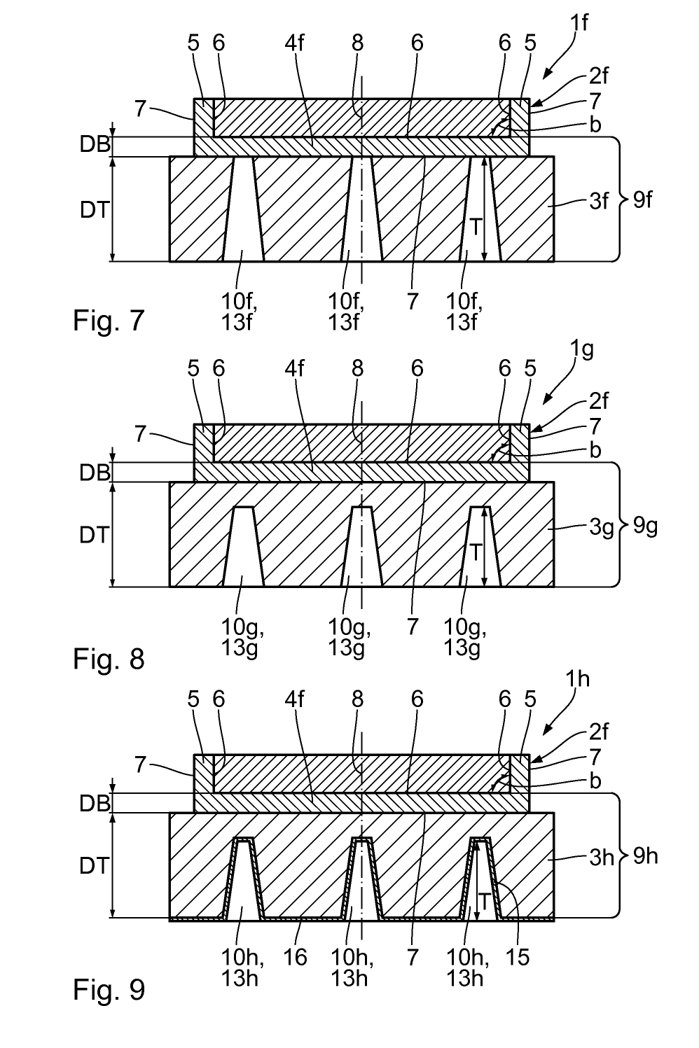

The following is a description, with reference to FIG. 6, of a sixth embodiment of the invention. Identical parts are denoted by the same reference numerals as in the first embodiment to the description of which reference is made. Differently designed parts having the same function are denoted by the same reference numerals with an e added to them. In the embodiment according to FIG. 6, the recesses 10e pass from the bottom 4e of the vessel 2e through the support plate 3e. They comprise in each case a support plate recess 13 in the support plate 3e. According to the embodiment shown in FIG. 6, the support plate recesses 13 pass through the entire support plate 3e in the direction of the central longitudinal axis 8. The support plate recesses 13 are in particular flush with the part of the recesses 10e arranged in the bottom 4a of the vessel 2a.

In other words, the recesses 10e extend from the side of the support plate 3e facing away from the bottom 4e of the vessel 2e in the direction of the central longitudinal axis 8 and pass through the support plate 3e up into the bottom 4e of the vessel 2e. According to the embodiment shown in FIG. 6, the recesses 10e are designed in the manner of a truncated cone. They expand continuously, with the dimensions in the region of the bottom 4e being smaller than those in the region of the support plate 3e. The recesses 10e in the base 9e, which are open to one side, in particular increase heat dissipation by heat radiation.

In this embodiment, the support plate 3e therefore also comprises at least two regions having different heat transfer coefficients U_{T1}, U_{T2}. The support plate 3e in particular has an inhomogeneous thickness DT_{XY}. In this embodiment, the following applies: DT<T<DT+D₀.

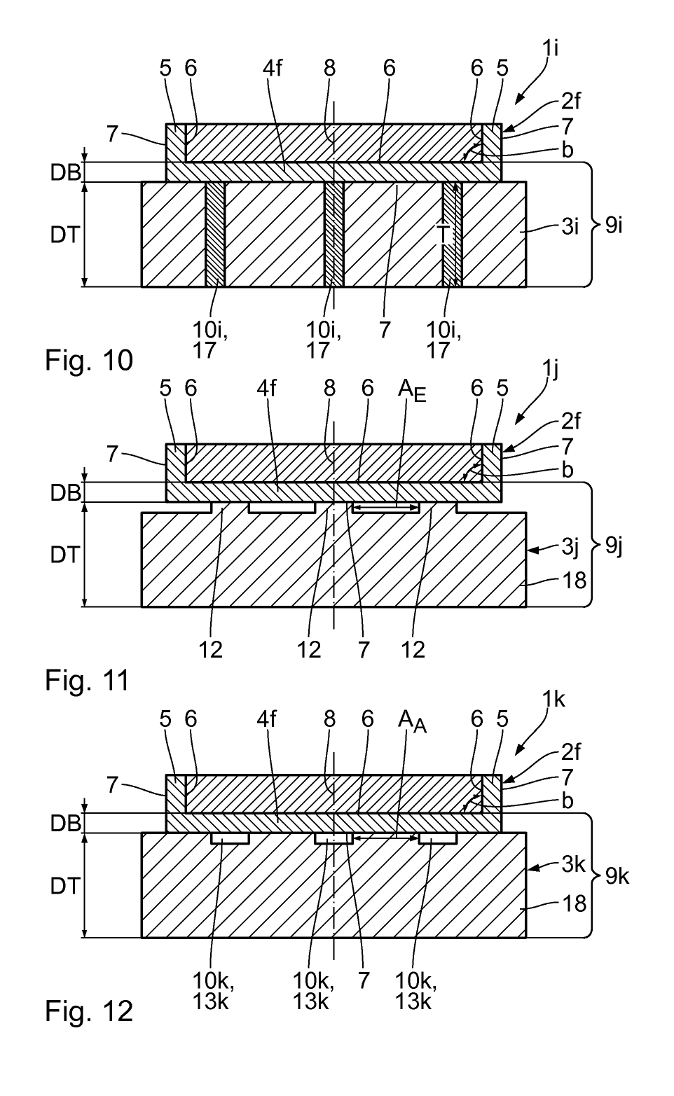

The following is a description, with reference to FIG. 7, of a seventh embodiment of the invention. Identical parts are denoted by the same reference numerals as in the first embodiment to the description of which reference is made. Differently designed parts having the same function are denoted by the same reference numerals with an f added to them. In the embodiment according to FIG. 7, the recesses 10f are identical to the support plate recesses 13f. They pass through the entire support plate 3f in the direction of the central longitudinal axis 8. They do however not reach the bottom 4f of the vessel 2f. In this embodiment, the depth T of the recesses 10f is equal to the thickness DT of the support plate 3f. In the embodiment according to FIG. 7, the outside 7 of the bottom 4f may be plane. It may in particular be plane-parallel to the inside 6 of the bottom 4f. In this embodiment, the bottom 4f may thus have a homogeneous thickness DB.

Naturally, it is also conceivable in the embodiment according to FIG. 7 to arrange recesses 10 in the bottom 4f. It is in particular conceivable to combine the embodiment according to FIG. 7 with an embodiment according to one of the examples shown in FIGS. 1 to 4.

The following is a description, with reference to FIG. 8, of an eigth embodiment of the invention. Identical parts are denoted by the same reference numerals as in the first embodiment to the description of which reference is made. Differently designed parts having the same function are denoted by the same reference numerals with a g added to them. In the embodiment according to FIG. 8, the recesses 10g extend in the direction of the central longitudinal axis 8 but only over a part of the support plate 3g. The depth T of the recesses 10g is in particular smaller than the thickness DT of the support plate 3g, with T<DT, in particular T<0.9 DT, in particular T<0.7 DT. On its side facing the bottom 4g, the support plate 3g has a plane surface.

The following is a description, with reference to FIG. 9, of a ninth embodiment of the invention. Identical parts are denoted by the same reference numerals as in the first embodiment to the description of which reference is made. Differently designed parts having the same function are denoted by the same reference numerals with an h added to them. In the embodiment according to FIG. 9, the recesses 10h are provided with a first coating 15. They are in particular lined, preferably entirely lined, with the first coating 15.

The function of the first coating 15 is to increase emissivity. The first coating 15 thus increases heat dissipation in the region of the recesses 10h. The first coating 15 is designed in such a way that the emissivity of the support plate 3h in the region of the recesses 10h is increased by at least 5%, in particular by at least 10%, compared to an uncoated support plate 3.

As an alternative or in addition to the first coating 15 in the region of the recesses 10h, a second coating 16 may be provided in the regions inbetween, in particular on the side of the support plate 3h facing away from the bottom 4f. The function of the second coating 16 is to reduce emissivity in the regions between the recesses 10h. The second coating 16 is designed in such a way that the emissivity of the support plate 3h in the regions between the recesses 10h is reduced by at least 5%, in particular by at least 10%, compared to an uncoated support plate 3.

Instead of being provided with the first coating 15, the surface of the support plate 3h may also be roughened in the region of the recesses 10h. Correspondingly, instead of providing the second coating 16, the surface of the support plate 3h may be particularly smooth, in particular polished, in the regions between the recesses 10h. The second coating 16 may also be a reflective coating. In this case, the reflection back into the support plate is increased which causes the dissipation of heat by radiation in the regions between the recesses to be reduced.

The following is a description, with reference to FIG. 10, of a tenth embodiment of the invention. Identical parts are denoted by the same reference numerals as in the first embodiment to the description of which reference is made. Differently designed parts having the same function are denoted by the same reference numerals with an i added to them. In the embodiment according to FIG. 10, the recesses 10i are filled with a filling 17. The filling 17 has a heat conductivity which is different from the heat conductivity of the support plate 3i in the regions outside the recesses 10i. The heat conductivity of the filling 17 may in particular be higher or lower than that of the support plate 3i in the remaining regions of the support plate 3i. The heat conductivity of the filling 17 in particular differs by at least 5%, in particular at least 10%, in particular at least 20% from the heat conductivity in the remaining regions of the support plate 3i.

The filling 17 consists of a material the melting point of which is higher than the melting point of silicon. The melting point of the filling 17 is in particular at least 1500° C., in particular at least 1600° C., preferably at least 1700° C. Suitable materials for the filling 17 are for example molybdenum, tungsten or a special steel which in particular contains a proportion of at least one of these elements.

In this embodiment, the recesses 10i preferably pass through the entire depth DT of the support plate 3i. The fillings 17 are therefore preferably also in direct contact with the bottom 4f of the vessel 2f.

As shown in FIG. 10, the recesses 10i may be hollow cylindrical. A design in the shape of a truncated cone or a cone as in the preceding embodiments is of course conceivable as well. Likewise, the recesses 10 to 10h of the preceding embodiments may also be hollow cylindrical.

The following is a description, with reference to FIG. 11, of an eleventh embodiment of the invention. Identical parts are denoted by the same reference numerals as in the first embodiment to the description of which reference is made. Differently designed parts having the same function are denoted by the same reference numerals with a j added to them. As in the embodiment according to FIG. 5, the support plate 3j of the embodiment according to FIG. 11 also comprises a base body 18 and projections 12. The projections 12 are arranged on the side of the support plate 3j facing the bottom 4f of the vessel 2f. As shown in FIG. 11, the outside 7 of the bottom 4f may be plane. The bottom 4f is thus in direct contact with the support plate 3j only in the region of the projections 12. In the embodiment shown in FIG. 11, the projections 12 are in each case arranged at a mutual distance A_{E} which is greater than the extension of the projections 12 in the direction perpendicular to the central longitudinal axis 8. The distance A_{E} is in particular at least 1.5 times, preferably at least twice the size of the extension of the projections 12 in the direction perpendicular to the central longitudinal axis 8.

Due to the projections 12, the bottom 4f of the vessel 2f is spaced from the base body 18 of the support plate 3j. In the embodiment according to FIG. 11, the medium is able to circulate between the bottom 4f of the vessel 2f and the base body 18 of the support plate 3j in the direction perpendicular to the central longitudinal axis 8, in other words it is able to flow in and out.

The following is a description, with reference to FIG. 12, of a twelfth embodiment of the invention. Identical parts are denoted by the same reference numerals as in the first embodiment to the description of which reference is made. Differently designed parts having the same function are denoted by the same reference numerals with a k added to them. In the embodiment according to FIG. 12, the recesses 10k are arranged as support plate recesses 13k on the side of the support plate 3k facing the bottom 4f of the vessel 2f. Therefore, they form hollow spaces which are bounded, in particular sealed off completely, by the support plate 3k on the one hand and by the bottom 4f on the other. The hollow spaces are filled with a material having a heat transfer coefficient which differs from the heat transfer coefficient of the material of the support plate 3k. They are preferably filled with a gas, in particular an inert gas or air. The heat transfer coefficient of the material in the recesses 10k in particular has a lower heat transfer coefficient than the material of the support plate 3k.

The recesses are in each case arranged at a mutual distance A_{A} in the direction perpendicular to the central longitudinal axis 8 which is in particular greater than the extension of the recesses 10k in this direction. The distance A_{A} is in particular at least 1.5 times, preferably at least twice the size of the extension of the recesses 10k in the direction perpendicular to the central longitudinal axis 8.

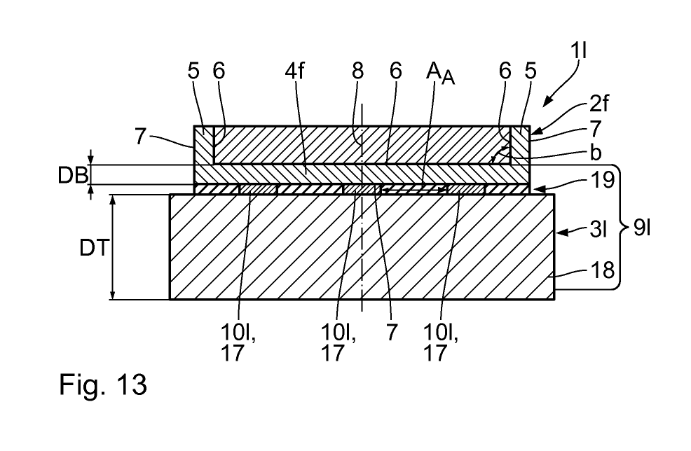

The following is a description, with reference to FIG. 13, of a thirteenth embodiment of the invention. Identical parts are denoted by the same reference numerals as in the first embodiment to the description of which reference is made. Differently designed parts having the same function are denoted by the same reference numerals with an 1 added to them. In the embodiment according to FIG. 13, the support plate 3l comprises an intermediate layer 19 between the base body 18 and the bottom 4f of the vessel 2f. The intermediate layer 19 comprises regions of different thermal conductivity. It also comprises the recesses 10l. The recesses 10l are preferably hollow cylindrical or conical. According to the embodiment shown in FIG. 10, they are filled with fillings 17 of a material having a higher or lower thermal conductivity than that of the remaining material of the intermediate layer 19. The thermal conductivity of the fillings 17 in particular differs from the thermal conductivity in the remaining regions of the intermediate layer 19 by at least 5%, in particular at least 10%, in particular at least 20%.

The fillings 17 consist of a material the melting point of which is higher than the melting point of silicon. The melting point of the fillings is in particular at least 1500° C., in particular at least 1600° C., preferably at least 1700° C. Suitable materials for the filling 17 are for example molybdenum, tungsten or a special steel which in particular contains a proportion of at least one of these elements.

Naturally, the recesses 10l may also be empty or filled with a gas. In this case, the intermediate layer 19 is a perforated plate. Such a perforated plate allows even already existing devices for the production of silicon blocks to be retrofitted easily.

The intermediate layer 19 has dimensions in the direction perpendicular to the central longitudinal axis 8 which just correspond to those of the bottom 4f of the vessel 2f.

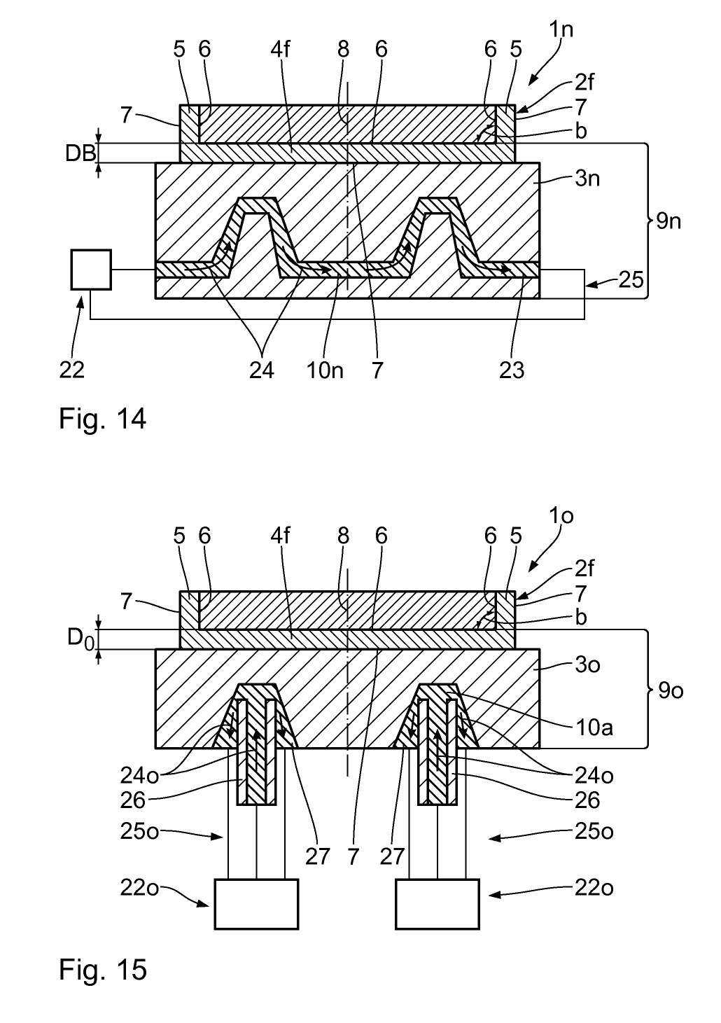

The following is a description, with reference to FIG. 14, of a fourteenth embodiment of the invention. Identical parts are denoted by the same reference numerals as in the first embodiment to the description of which reference is made. Differently designed parts having the same function are denoted by the same reference numerals with an n added to them. In the embodiment according to FIG. 14, the recess 10n is a cooling duct in the support plate 3n. The cooling duct is connected to a cooling device 22 which is only outlined in FIG. 14. The cooling duct can be acted upon by a cooling medium 23 in particular by means of the cooling device 22. The cooling system is therefore an active cooling for dissipating the heat through the bottom 4f. When the cooling device 22 is operated, the cooling medium 23 flows through the cooling duct in a flow direction 24. Preferably, a closedloop cooling circuit 25 is provided for the cooling medium 23. The cooling duct is in particular arranged in the support plate 3n in a meandering pattern. The cooling duct comprises portions which have different distances to the bottom 4f of the vessel 2f. Due to the different distances to the bottom 4f, the cooling duct runs through regions of the base 9n which have different temperatures when the melt cools down. The cooling duct is thus arranged in the base 9n in such a way that there is a locally different temperature gradient between the inside 6 of the bottom 4f and the cooling duct when the melt cools down. This results in a locally increased dissipation of heat through the bottom 4f.

In principle, the cooling duct may reach up to the bottom 4f of the vessel 2f. In this case, it is partially bounded by the bottom 4f of the vessel 2f. Alternatively, as shown in FIG. 14, the cooling duct may also be entirely arranged in the support plate 3n.

The cooling duct preferably has a constant expansion in the direction of the central longitudinal axis 8 across its entire length in the region of the support plate 3n. A constant flow cross section is conceivable as well. Alternatively, however, it is conceivable as well to design the cooling duct in such a way as to have a varying expansion across its length when seen in the direction of the central longitudinal axis 8. This allows the dissipation of heat through the bottom to be influenced as well.

The cooling medium 23 is in particular a fluid, preferably a gas, in particular an inert gas such as helium or argon.

It is furthermore conceivable to provide several cooling ducts in the support plate 3n. They may be acted upon with coolant 23 via a common cooling device 22 or by several cooling devices 22.

The cooling duct ensures a particularly efficient dissipation of heat from the support plate 3n. The cooling device 22 allows an inhomogeneous temperature field to be generated on the side of the support plate 3m facing the bottom 4f of the vessel 2f and therefore both on the outside 7 and on the inside 6 of the bottom 4f.

A particular advantage of the embodiment according to FIG. 14 is that the local increase of the dissipation of heat through the bottom 4f of the vessel 2f is controllable by means of the cooling device 22.

The following is a description, with reference to FIG. 15, of a fifteenth embodiment of the invention. Identical parts are denoted by the same reference numerals as in the first embodiment to the description of which reference is made. Differently designed parts having the same function are denoted by the same reference numerals with an o added to them. In the embodiment according to FIG. 15, the recesses 10o in the support plate 3o correspond to those of the embodiments according to one of FIGS. 6 to 9. For active cooling, in other words heat dissipation, in the region of the recesses 10n, one or multiple cooling devices 22o are provided as in the embodiment according to FIG. 14. In this embodiment, each of the recesses 10o is provided with a separate cooling circuit 25o. The cooling circuit 25o comprises one coolant supply line 26 and one coolant return line 27 which are in each case arranged in the centre of the recess 10o. The coolant supply line 26 is preferably in each case parallel to the central longitudinal axis 8. The coolant return line 27 is in each case concentric with the coolant supply line 26 in the region of the recess 10o. Supply of the coolant 23 may therefore occur substantially along the temperature gradient. Likewise, discharge of the coolant 23 may also occur substantially along the temperature gradient.

Each of the cooling circuits 25o comprises a separate cooling device 22o. A common cooling device 22o is however conceivable as well.

In this embodiment, the volume flow of the coolant 23 through the base 90 in the direction perpendicular to the central longitudinal axis 8 is variable, in other words it is dependent on the position relative to the central longitudinal axis 8.

In the illustrated embodiment, the recesses 10o have a depth T which is lower than the depth DT of the support plate 3o. Corresponding to the embodiments described hereinbefore, the recesses 10o may also reach up to the bottom 4f of the vessel 2f, with T=DT, or reach into the bottom 4f of the vessel 2f, with DT+D₀>T>DT.

The geometry of the recesses 10o may also be varied according to the embodiments described hereinbefore. The recesses 10o may in particular be in the shape of a truncated cone or of a cylinder.

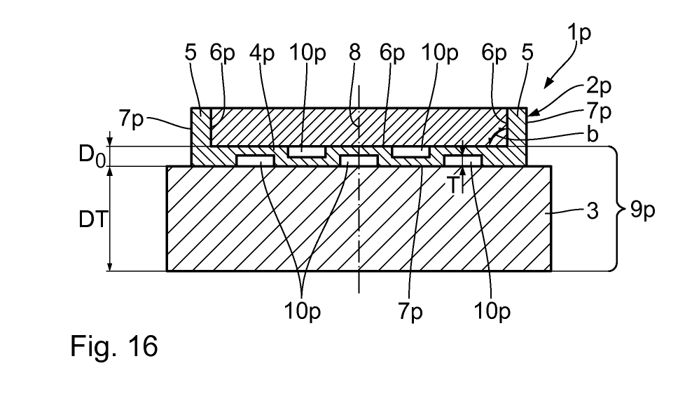

The following is a description, with reference to FIG. 16, of another embodiment of the invention. Identical parts are denoted by the same reference numerals as in the embodiment according to FIG. 1 to the description of which reference is made. Differently designed parts having the same function are denoted by the same reference numerals with a p added to them. While the inside 6 of the bottom 4 is plane according to the embodiment of FIG. 1, the recesses 10p in the embodiment according to FIG. 16 are arranged on the inside 6p as well as on the outside 7p of the bottom 4p. Here, the recesses 10p do not face the recesses 10p of the outside 7p. In other words, in the direction perpendicular to the central longitudinal axis 8 the recesses 10p on the inside 6p are each arranged offset to those on the outside 7p. It is to be understood by an offset arrangement that the recesses 10p on the inside 6p and the outside 7p of the bottom 4p in the direction of the central longitudinal axis 8 do at least not exactly align. They may, however, be arranged partially overlapping. Preferably, the recesses 10p on the inside 6p and the outside 7p of the bottom 4p in the direction of the central longitudinal axis 8 are arranged in a non-overlapping manner. Accordingly, the recesses 10p of the outside 7p are arranged offset to those on the inside 6p. As in the previously described embodiments a plurality of recesses 10p is provided, which, when the device is operated, form heat sinks and thus a plurality of nucleation places. In FIG. 16 an embodiment with cylindrical recesses 10p is shown. Naturally, the recesses 10p may have a geometry differing therefrom. The recesses 10p on the inside 6p of the bottom 4p may be designed identical to the recesses 10p on the outside 7p of the bottom 4p. The recesses 10p on the inside 6p of the bottom 4p may also have a geometric design differing from the one of the recesses 10p on the outside 7p of the bottom 4p.

Naturally, the details of the embodiments shown in the various Figures may be randomly combined. For example, it is in particular conceivable to randomly combine the structure of the bottom 4 to 4e of the vessel 2 to 2e according to one of the embodiments shown in FIGS. 1 to 6 with the embodiments of the support plate 3 to 3o according to one of the illustrated embodiments.

Likewise, one or several cooling devices 22 as shown in FIGS. 14 and 15 may also be provided in all other embodiments.

The intermediate layer 19 according to the embodiment shown in FIG. 13 may particularly easily combined with the other embodiments.

Coatings 15, 16 as described with reference to the embodiment according to FIG. 9 may also be provided in the other embodiments. They may in particular be provided in the region of the bottom 4 to 4f of the vessel 2 to 2f. Likewise, the bottom 4 to 4f may for example be roughened or polished.

Other combinations are conceivable as well.

What is claimed is:

1. A device for the production of silicon blocks, the device comprising
a. a vessel for receiving a silicon melt, the vessel comprising
i. a bottom;
ii. an inside;
iii. an outside; and
iv. a central longitudinal axis,
b. with the bottom
i. having an extension in a direction perpendicular to the central longitudinal axis; and
ii. along its extension in the direction perpendicular to the central longitudinal axis comprising at least two regions with different heat transfer coefficients.

2. A device according to claim 1, wherein the bottom has an inhomogeneous thickness, and wherein the bottom has a constant thermal conductivity.

3. A device according to claim 2, wherein the bottom comprises a multitude of recesses.

4. A device according to claim 3, wherein the recesses are provided on the outside of the bottom.

5. A device according to claim 3, wherein some of the recesses are arranged on the inside of the bottom and some of the recesses are arranged on the outside of the bottom.

6. A device according to claim 5, wherein the recesses on the inside of the bottom are arranged in the direction perpendicular to the central longitudinal axis offset to those on the outside.

7. A device according to claim 3, wherein the recesses have a depth in the range of 0.5 mm to 2 cm in the direction of the central longitudinal axis.

8. A device according to claim 3, wherein the recesses have an expansion in the range of 1 mm to 20 cm in the direction perpendicular to the central longitudinal axis.

9. A method for the production of a device according to the invention, wherein in order to produce the vessel, a green body is produced in a first step.

10. A method according to claim 9, wherein the bottom of the vessel is structured by means of a punch before the green body has cured.

11. A method according to claim 9, wherein structuring of the bottom of the vessel takes place in an after-treatment step when the green body has cured.

12. A device for the production of silicon blocks, the device comprising
a vessel for receiving a silicon melt, the vessel comprising
a bottom;
an inside;
an outside; and
a central longitudinal axis; and
at least one support plate
which is at least partially in direct contact with the bottom and
which forms a base together with the bottom; and
means for generating an inhomogeneous temperature field on the inside of the bottom.

13. A device according to claim 12, wherein the base has an inhomogeneous heat transfer coefficient.

14. A device according to claim 12, wherein the at least one support plate comprises at least two regions having different heat transfer coefficients.

15. A device according to claim 12, wherein the at least one support plate has an inhomogeneous thickness.

16. A device according to claim 12, wherein the bottom has an inhomogeneous thickness.

17. A device according to claim 12, wherein the support plate comprises a multitude of recesses.

18. A device according to claim 12, wherein the means for generating an inhomogeneous temperature field on the inside of the bottom comprise a cooling duct which can be acted upon by a coolant by means of at least one cooling device.

19. A device according to claim 18, wherein the cooling duct is arranged in the support plate in a meandering pattern.

20. A device according to claim 18, wherein a separate cooling circuit is provided for each recess.
